(19) United States
(12) Patent Application Publication
(10) Pub. No.: US 2025/0192520 A1
(43) Pub. Date: Jun. 12, 2025

(54) SEMICONDUCTOR COMPONENT AND METHODS FOR PRODUCING A SEMICONDUCTOR COMPONENT

(71) Applicant: ams-OSRAM International GmbH, Regensburg (DE)

(72) Inventors: Bruno JENTZSCH, Regensburg (DE); Christoph EICHLER, Donaustauf (DE)

(73) Assignee: ams-OSRAM International GmbH, Regensburg (DE)

(21) Appl. No.: 18/846,313

(22) PCT Filed: Feb. 2, 2023
(86) PCT No.: PCT/EP2023/052544

§ 371 Date: Sep. 12, 2024

(30) Foreign Application Priority Data
Mar. 16, 2022 (DE) 10 2022 106 079.9

(51) Int. Cl. H01S 5/30; H01S 5/028; H01S 5/343

(52) U.S. Cl. CPC H01S 5/3054; H01S 5/028; H01S 5/343; H01S 2301/17

(57) ABSTRACT

A semiconductor laser component is specified, having an n-doped semiconductor layer, an active layer and a p-doped semiconductor layer, the active layer being disposed between the n-doped semiconductor layer and the p-doped semiconductor layer. The active layer is designed to generate radiation. The p-doped semiconductor layer includes at least one activated region and at least one unactivated region, with the unactivated region in particular directly bordering an outcoupling facet. The at least one unactivated region has a higher hydrogen fraction and/or a lower electrical conductivity than the activated region. Also specified are methods for producing a semiconductor laser component.

### CROSS-REFERENCE TO RELATED APPLICATIONS

The present application is a national stage entry from International Application No. PCT/EP2023/052544, filed on Feb. 2, 2023, published as International Publication No. WO 2023/174616 Al on Sep. 21, 2023, and claims priority to German Patent Application No. 10 2022 106 079.9, filed Mar. 16, 2022, the disclosures of all of which are hereby incorporated by reference in their entireties.

### FIELD

A semiconductor laser component and a method for producing a semiconductor laser component are provided.

### BACKGROUND

A task to be solved is to provide a semiconductor laser component which can be operated particularly efficiently. A further task to be solved is to provide methods, with which a semiconductor laser component, which can be operated particularly efficiently, can be produced.

### SUMMARY

According to at least one embodiment, the semiconductor laser component comprises an n-doped semiconductor layer. The n-doped semiconductor layer is based, for example, on a III-V compound semiconductor. For example, the n-doped semiconductor layer comprises GaN and/or AlGaN. Preferably, the n-doped semiconductor layer comprises dopants. The n-doped semiconductor layer can, in particular, be n-conductive.

According to at least one embodiment, the semiconductor laser component comprises an active layer. The active layer comprises, for example, a p-n junction, a heterostructure, a single quantum well structure (SQW) and/or a multi-quantum well structure (MQW).

According to at least one embodiment, the semiconductor laser component comprises a p-doped semiconductor layer. The p-doped semiconductor layer is based, for example, on a III-V compound semiconductor. For example, the p-doped semiconductor layer comprises GaN and/or AlGaN. Preferably, the p-doped semiconductor layer comprises dopants. For example, the dopant is magnesium. The p-doped semiconductor layer can, in particular, be p-conductive.

The semiconductor laser component can comprise a stacking direction. The stacking direction is a direction along which layers of the semiconductor laser component are arranged one above the other and/or in succession.

The semiconductor laser component may comprise a main extension direction and a further main extension direction. The main extension direction and the further main extension direction span a main extension plane of the semiconductor laser component. The stacking direction runs perpendicular to the main extension plane.

The semiconductor laser component comprises, for example, a resonator axis. The resonator axis is preferably aligned parallel to the main extension plane. In particular, the main extension direction can run in parallel to the resonator axis of the semiconductor laser component. The further main extension direction runs perpendicular to the main extension direction in the main extension plane. In particular, the resonator axis is an axis that extends from one side surface of the semiconductor laser component to an opposite side surface of the semiconductor laser component. For example, an outcoupling facet can be arranged on the one side surface. A back facet, for example, can be arranged on the opposite side surface. The outcoupling facet is, for example, configured to outcouple the electromagnetic radiation generated in the semiconductor laser component into the medium surrounding the semiconductor laser component.

According to at least one embodiment of the semiconductor laser component, the active layer is arranged between the n-doped semiconductor layer and the p-doped semiconductor layer. The main extension plane of the layers preferably each runs perpendicular to the stacking direction. For example, the layers follow one another along the stacking direction.

According to at least one embodiment of the semiconductor laser component, the active layer is designed to generate radiation. The active layer is, for example, configured to generate radiation, in particular to generate coherent radiation. The generated radiation is outcoupled, for example, at an outcoupling facet of the semiconductor laser component. The outcoupling facet forms a side surface of the semiconductor laser component or is arranged at a side surface of the semiconductor laser component. The outcoupling facet extends perpendicular to the resonator axis. The semiconductor laser component may comprise a radiation exit surface. The radiation exit surface may correspond to the outcoupling facet.

According to at least one embodiment, the semiconductor laser component comprises an undoped semiconductor layer. The undoped semiconductor layer is arranged, for example, between the active layer and the p-doped semiconductor layer. The undoped layer can be based on a semiconductor material. Optionally, the semiconductor laser component can also comprise further layers, in particular further undoped, n-doped and/or p-doped semiconductor layers.

According to at least one embodiment, the p-doped semiconductor layer comprises at least one activated region and at least one unactivated region.

The at least one unactivated region and the at least one activated region can, for example, extend over the entire layer thickness of the p-doped semiconductor layer. The layer thickness of the p-doped semiconductor layer is an extension of the p-doped semiconductor layer along the stacking direction. This means that the at least one unactivated region and the at least one activated region are arranged laterally next to each other, for example. For example, the activated region is arranged adjacent to the unactivated region in a main extension direction that runs parallel to the resonator axis. For example, the activated region can at least partially laterally enclose the unactivated region. This means that the activated region is arranged adjacent to the unactivated region in at least two mutually different directions, both of which run parallel to the main extension plane of the semiconductor laser component. In particular, the unactivated region and the activated region of the p-doped semiconductor layer can be directly adjacent to each other. Thereby, the unactivated region and the activated region of the p-doped semiconductor layer can be separated by a transition region formed by the unactivated and the activated region.

The activated region of the p-doped semiconductor layer can comprise, at least in places or completely along the main extension direction and/or along the further main extension direction, an extension that is smaller than or equal to the extension of the p-doped semiconductor layer. The unactivated region of the p-doped semiconductor layer extends, for example, along the further main extension direction completely over the extent of the p-doped semiconductor layer.

The unactivated region of the p-doped semiconductor layer can comprise an extension parallel to the resonator axis that is smaller than the extension of the p-doped semiconductor layer along this direction. Along the further main extension direction, perpendicular to the resonator axis, the unactivated region can comprise an extension that is smaller than or equal to the extension of the p-doped semiconductor layer along the further main extension direction.

The p-doped semiconductor layer comprises, for example, one, for example more than one unactivated region. The p-doped semiconductor layer comprises, for example, one, for example more than one activated region. In particular, the p-doped semiconductor layer can comprise two unactivated regions and one activated region. The unactivated regions are arranged at a distance from each other, for example. The activated region can be arranged at least partially between the unactivated regions. If the p-doped semiconductor layer comprises more than one unactivated region, the unactivated regions can have the same shape or different shapes.

The at least one unactivated region of the p-doped semiconductor layer is, for example, an epitaxially grown p-doped semiconductor layer. This can comprise the same material as the activated region. The unactivated region can be a region that was not activated during the manufacturing process of the semiconductor laser component (as grown). This can mean that the unactivated region was not thermally activated and/or that additional hydrogen was added to the unactivated region. The activated region can be a region that was activated during the manufacturing process of the semiconductor laser component. This can mean that the activated region has been thermally activated and/or that hydrogen has not been added additionally to the activated region.

According to at least one embodiment, the at least one unactivated region comprises a higher hydrogen content and/or a lower electrical conductivity than the activated region.

The at least one unactivated region can comprise a lower electrical conductivity relative to the at least one activated region. The electrical conductivity of the unactivated region can, at least in places, be lower than the electrical conductivity of the activated region, for example by at least a factor of 2, for example by at least a factor of 4, in particular by at least a factor of 10. The at least one unactivated region can be electrically insulating at least in places. The electrical conductivity of the unactivated region may comprise a gradient. For example, the electrical conductivity in the unactivated region decreases with increasing distance from the activated region.

The unactivated region of the p-doped semiconductor layer can additionally or alternatively comprise a higher hydrogen content relative to the activated region of the p-doped semiconductor layer. The hydrogen can, for example, be present free or bound, in particular as an Mg—H complex. The hydrogen content in the unactivated region can be the same over the entire unactivated region; alternatively, the hydrogen content can also follow a gradient or be distributed inhomogeneously. For example, the hydrogen content in the unactivated region increases in a direction parallel to the main extension plane of the semiconductor laser component with increasing distance from the activated region.

According to at least one embodiment, the semiconductor laser component comprises an n-doped semiconductor layer, an active layer and a p-doped semiconductor layer, wherein the active layer is arranged between the n-doped semiconductor layer and the p-doped semiconductor layer. The active layer is designed to generate radiation. Furthermore, the p-doped semiconductor layer comprises at least one activated region and at least one unactivated region, wherein the at least one unactivated region comprises a higher hydrogen content and/or a lower electrical conductivity than the activated region.

An advantage of the semiconductor laser component is that the semiconductor laser component comprises a partially unactivated p-doped semiconductor layer. Thus, the p-doped semiconductor layer of the semiconductor laser component can comprise different electrical conductivities. An energization of the semiconductor laser component in regions with different electrical conductivity differs from each other and can thus be controlled in a simplified manner.

Furthermore, the semiconductor laser component advantageously comprises a low-absorption facet and/or a low-absorption region at the facet, preferably at the outcoupling facet. This low-absorption region is the unactivated region. The unactivated region can, for example, be formed selectively locally, for example in the region at the facet. The absorption of the unactivated region can, for example, be reduced by a factor of 10 compared to the activated region. A reduction of the absorption can be advantageous, as less heating due to absorption in this region occurs. This can reduce the failure rate due to optical damage, COD (Catastrophic Optical Damage), on the facets, especially on the outcoupling facet. Furthermore, due to the unactivated region an energization in the region of the facet is kept low during operation of the semiconductor laser component. The stability and/or the maximum possible output power of the semiconductor laser component can thus be increased.

According to at least one embodiment of the semiconductor laser component, at least one cover layer is arranged on the at least one unactivated region of the p-doped semiconductor layer. The at least one cover layer can comprise a hydrogen-impermeable material. As a result, the at least one cover layer can at least partially reduce and/or prevent an activation of the p-doped semiconductor layer arranged between the cover layer and the active layer. For example, the cover layer can be at least partially applied to the activated region of the p-doped semiconductor layer.

An advantage of this embodiment is that due to the cover layer an energization of the semiconductor laser component can be at least partially reduced in the region of the cover layer and/or between the cover layer and the n-doped semiconductor layer. If the cover layer is arranged close to the outcoupling facet, an energization in the region of the outcoupling facet can advantageously be reduced or avoided. A further advantage of this embodiment of the semiconductor laser component is that the cover layer does not have to be removed during the manufacturing process. A semiconductor laser component according to this embodiment can be manufactured in an uncomplicated manner, for example.

According to at least one embodiment, a layer stack is arranged on the at least one unactivated region of the p-doped semiconductor layer, and the layer stack comprises at least one cover layer and at least one further cover layer. The layer stack comprises, for example, a cover layer and a further cover layer. In particular, the layer stack can comprise at least one cover layer and at least one further cover layer. For example, the layer stack is formed from at least two cover layers and at least one further cover layer. The cover layers and the at least one further cover layer can, for example, be arranged alternately. Preferably, a refractive index of the layer stack is adapted to a refractive index of a layer which is arranged, for example, adjacent to the p-doped semiconductor layer. The refractive index of the layer stack is, for example, the refractive index averaged over the layers of the layer stack. In other words, the layer stack can comprise an effective refractive index. The refractive index can, for example, be averaged weighted with the mode intensity. The layer may, for example, be a contact layer. Adapted means here and in the following in particular that the refractive indices can take similar or identical values. For example, the refractive indices can differ from each other by a maximum of 20%.

The cover layer is, for example, impermeable to hydrogen. For example, the cover layer can be based on SiN and/or n-GaN.

The further cover layer can, for example, also be based on SiN and/or n-GaN. Alternatively or additionally, the further cover layer may comprise other materials and/or oxides and/or nitrides, for example SiO2 and/or preferably TiO2.

An advantage of this embodiment of the semiconductor laser component is that the semiconductor laser component can comprise a larger maximum difference between the electrical conductivity of the activated region and the electrical conductivity of the unactivated region as well as between the hydrogen content of the two regions. This can be achieved by reducing the diffusion and thus an evaporation of hydrogen due to the layer stack. An activation of the region of the p-doped semiconductor layer adjacent to the layer stack can be reduced.

Furthermore, the layer stack can comprise a refractive index that is adapted to other refractive indices in the semiconductor laser component, so that a refractive index jump in the semiconductor laser component can at least be reduced. Thereby, for example, the efficiency and/or the beam quality of the semiconductor laser component can be increased. The refractive index of the layer stack is, for example, adapted to the refractive index of a contact layer, which is arranged on the side of the p-doped semiconductor layer facing away from the active layer.

According to at least one embodiment of the semiconductor laser component, at least one intermediate layer is arranged on the at least one unactivated region of the p-doped semiconductor layer, and the intermediate layer comprises a dielectric. The intermediate layer can, for example, comprise a dielectric or be formed entirely from it. For example, the intermediate layer contains at least one oxide, nitride and/or oxynitride. In particular, the intermediate layer comprises Al, Ce, Ga, Hf, In, Mg, Nb, Rh, Sb, Si, Sn, Ta, Ti, Zn and/or Zr in connection with an oxide, nitride and/or oxynitride. The intermediate layer also preferably has a refractive index that is adapted to the refractive index of the contact layer.

An idea of this embodiment is that an energization of the outcoupling facet is reduced due to the electrically non-conductive or at least poorly conductive intermediate layer.

According to at least one embodiment, the at least one cover layer comprises SiN and/or n-doped GaN. These materials can, for example, be impermeable to hydrogen.

According to at least one embodiment, a side of the p-doped semiconductor layer facing away from the active layer comprises a damage at least partially in the at least one unactivated region of the p-doped semiconductor layer. The damage is, for example, a damaged lattice structure. The damaged lattice structure is arranged, for example, on a side of the p-doped semiconductor layer facing away from the active layer. Preferably, the region with the damaged lattice structure can form a layer which is aligned essentially parallel to the main extension plane of the semiconductor laser component and at least partially forms a surface of the p-doped semiconductor layer facing away from the active layer. The layer with the damaged lattice structure has an extension along the stacking direction which, for example, corresponds to at most the layer thickness of the p-doped semiconductor layer and/or is at most 50 nm, for example. Preferably, the extension of the layer with the damaged lattice structure is in the range from including 0.1 nm up to and including 30 nm. The layer with the damaged lattice structure in the unactivated region can comprise a lower electrical conductivity than the undamaged unactivated region. The layer with the damaged lattice structure is preferably adjacent to the outcoupling facet.

As the region with the damage may comprise a lower conductivity than the undamaged region, an energization of the outcoupling facet can be reduced.

According to at least one embodiment, the at least one unactivated region comprises an extension of at least 500 nm and at most 150 μm in a lateral direction which runs parallel to the main extension plane of the semiconductor laser component. In particular, the lateral direction may be a direction parallel to the resonator axis of the semiconductor laser component. Preferably, the extension of the unactivated region along the resonator axis can be between 1 μm and 100 μm, for example at least 3 μm and at most 50 μm and particularly preferably at least 10 μm and at most 30 μm. The unactivated region can be directly adjacent to the outcoupling facet or to the back facet and extend along the resonator axis into the semiconductor laser component.

An idea of this embodiment is that the unactivated region, which, for example, is directly adjacent to the outcoupling facet, comprises an extension along the resonator axis that efficiently reduces or prevents energization of the outcoupling facet.

According to at least one embodiment, the activated region of the p-doped semiconductor layer and the at least one unactivated region of the p-doped semiconductor layer are arranged next to each other in a lateral direction which runs parallel to the main extension plane of the semiconductor laser component. The activated region and the unactivated region can be, in particular, arranged directly next to each other. The activated region and the unactivated region can comprise similar properties in a transition region. In other words, the activated region can merge smoothly into the unactivated region. Thus, there may be a transition region between the activated and the unactivated region, in which the activated region transitions into the unactivated region.

A transition of the activated region into the unactivated region facilitates the production of the p-doped semiconductor layer in comparison to an abrupt transition.

According to at least one embodiment, the semiconductor laser component comprises at least one electrical contact. The at least one electrical contact can be formed flat. Further, the at least one electrical contact can be intended for energization. In particular, the at least one electrical contact is electrically conductive. The at least one electrical contact can, for example, be configured for energizing the activated region of the p-doped semiconductor layer. The electrical contact can comprise a metal and/or a metal alloy. In particular, the at least one electrical contact can comprise Al, Au, Ag, Ni, Pd, Pt and/or Ti.

The semiconductor laser component can comprise at least one further electrical contact. The semiconductor laser component comprises, for example, the electrical contact adjacent to the p-doped semiconductor layer and the further electrical contact adjacent to the n-doped semiconductor layer. The at least one electrical contact is arranged, for example, on a top side of a semiconductor body. The at least one further contact is arranged, for example, on a bottom side of the semiconductor body. The semiconductor body can comprise the p-doped semiconductor layer, the active layer and the n-doped semiconductor layer as well as optionally the cover layer, the further cover layer and/or the intermediate layer. The top side of the semiconductor body is, for example, the side of the p-doped semiconductor layer, the cover layer, the further cover layer and/or the intermediate layer facing away from the active layer. The bottom side of the semiconductor body is, for example, the side of the n-doped semiconductor layer facing away from the active layer.

According to at least one embodiment, the at least one electrical contact is electrically conductively connected to the activated region. In other words, the at least one electrical contact can be configured to energize the activated region of the p-doped semiconductor layer.

According to at least one embodiment, the at least one unactivated region is at least partially arranged between the at least one electrical contact and the active layer. In other words, the at least one electrical contact can be partially arranged on the unactivated region of the p-doped semiconductor layer. For example, the electrical contact can completely cover a top side of the semiconductor body.

An advantage of this embodiment is that the electrical contact can be applied in a simplified manner. An adjacency of the at least one electrical contact to the facet, for example to the back facet, in particular to the outcoupling facet, also improves the heat dissipation from the facet.

According to at least one embodiment, at least in places a contact layer is arranged on the side of the p-doped semiconductor layer facing away from the active layer. In other words, the contact layer is arranged, for example, at least in places on the top side of the semiconductor body. The contact layer is, for example, a p-type contact layer. This can, for example, be arranged directly adjacent to the electrical contact and/or, for example, directly between the electrical contact and the p-doped semiconductor layer. The contact layer is configured, for example, to inject current into the p-doped semiconductor layer. The contact layer is made, for example, from one or more transparent, electrically conductive oxides, TCOs (transparent conductive oxides), or comprises at least one such material.

This exemplary embodiment is based, among other things, on the idea that a wave guidance in the semiconductor laser component is improved due to the contact layer.

According to at least one embodiment of the semiconductor laser component, the at least one unactivated region of the p-doped semiconductor layer is adjacent to a side of the semiconductor laser component at which the radiation exit surface is arranged. The radiation exit surface may correspond to the outcoupling facet of the semiconductor laser component. The radiation exit surface can, for example, only extend over a part of the outcoupling facet. Preferably, the outcoupling facet is a side surface of the semiconductor laser component that extends perpendicular to the resonator axis. For example, the unactivated region of the p-doped semiconductor layer is arranged at the outcoupling facet. The unactivated region is arranged adjacent to the outcoupling facet, for example, at least in the region of the extension of the radiation exit surface along the further main extension direction. As the radiation can be scattered, the unactivated region advantageously extends beyond the radiation exit surface in a direction parallel to the main extension plane and perpendicular to the resonator axis. The semiconductor laser component is, for example, an edge-emitting semiconductor laser.

An advantage of this embodiment of the semiconductor laser component is that the energization is reduced, particularly at the radiation exit surface. Thus, the failure rate of the semiconductor laser component due to optical damage to the outcoupling facet can be reduced.

Furthermore, a method for producing a semiconductor laser component is provided. The semiconductor laser component is preferably producible by a method described herein. In other words, all features disclosed for the semiconductor laser component are also disclosed for the method for producing a semiconductor laser component and vice versa.

According to at least one embodiment of the method for producing a semiconductor laser component, the method comprises a method step in which an n-doped semiconductor layer, an active layer and a p-doped semiconductor layer are epitaxially grown on top of each other, wherein the active layer is arranged between the n-doped semiconductor layer and the p-doped semiconductor layer.

According to at least one embodiment, the method comprises a method step in which only a partial region of the p-doped semiconductor layer is activated. The partial region of the p-doped semiconductor layer can be activated by means of heating, in particular by means of rapid thermal annealing, RTA. By means of RTA, for example, the electrical conductivity can be improved. Thereby, the p-doped semiconductor layer is, for example, heated to temperatures between 400° C. and 1000° C., for example also to more than 1000° C., and then cooled. Thereby, the hydrogen bound in the p-doped semiconductor layer can be at least partially evaporated.

The partial region can be, in particular, a contiguous region of the p-doped semiconductor layer. To ensure that only the partial region of the p-doped semiconductor layer is activated, for example, evaporation of hydrogen from the remaining region of the p-doped semiconductor layer can be reduced, in particular prevented. The region of the p-doped semiconductor layer that is not activated is an unactivated region.

In the p-doped semiconductor layer, the hydrogen can move during activation at least partially in a direction that is not perpendicular to the main extension plane of the semiconductor laser component. Thus, it is possible that the transition between the unactivated region and the activated region of the p-doped semiconductor layer does not comprise a clearly defined interface but a transition region. Activating here means that the electrical conductivity is increased by reducing crystal lattice defects and/or by reducing the hydrogen content. This can be achieved, for example, by heating to temperatures between 400° C. and 1000° C., for example also to more than 1000° C.

According to at least one embodiment of the method for producing a semiconductor laser component, an n-doped semiconductor layer, an active layer and a p-doped semiconductor layer are epitaxially grown on top of one another, wherein the active layer is arranged between the n-doped semiconductor layer and the p-doped semiconductor layer. Subsequently, only a partial region of the p-doped semiconductor layer is activated.

An advantage of this embodiment of the method is that a semiconductor laser component can be produced with a p-doped semiconductor layer that is activated only in places.

According to at least one embodiment of the method for producing a semiconductor laser component, prior to activating the partial region of the p-doped semiconductor layer, at least one cover layer is applied to at least one further partial region of the p-doped semiconductor layer which is different from the partial region. For example, the at least one cover layer is applied completely to the further partial region of the p-doped semiconductor layer that is different from the partial region. The at least one cover layer is preferably formed impermeable to hydrogen. For example, the at least one cover layer comprises n-doped GaN and/or SiN. The at least one cover layer can be applied, for example, by chemical vapor deposition (CVD), atomic layer deposition (ALD) or directly in the epireactor. For example, the layer thickness, the expansion of the layer in the stacking direction, is at least one monolayer and up to 2 μm. For example, the layer thickness is at most 1 μm, for example at most 200 nm or for example at most 100 nm.

Thus, the region of the p-doped semiconductor layer to which the at least one cover layer is applied cannot be activated or is activated to a lesser extent than a region not covered by the cover layer when heated.

Further cover layers can also be applied. For example, a layer stack, which comprises at least one cover layer and at least one further cover layer can be applied.

In order to reduce an evaporation of hydrogen, the semiconductor laser component can be aligned during activation in particular in such a way that hydrogen evaporation through the cover layer is at least reduced.

An idea of this embodiment is to provide a method by which only a part of the p-doped semiconductor layer can be activated in an uncomplicated manner.

According to at least one embodiment of the method for producing a semiconductor laser component, the cover layer is applied directly in the epireactor to at least one further partial region of the p-doped semiconductor layer. The cover layer can, for example, be formed impermeable to hydrogen.

An advantage of this embodiment is that impurities on the p-doped semiconductor layer can be prevented or at least reduced. The manufacturing process can thus be simplified, for example, in that at least fewer cleaning steps are required. In addition, by applying the cover layer in the epireactor, the p-doped layer is protected in the at least one further partial region in the further manufacturing process. The contact stress can be improved by reducing impurities.

According to at least one embodiment of the method for producing a semiconductor laser component, the at least one cover layer is removed after the activation step. The cover layer can, for example, be removed by wet chemical means. Alternatively or additionally, the layer stack can be partially or completely removed after the activation step. The layer stack can, for example, be removed by wet chemical means.

An advantage of this embodiment is that better heat dissipation of the semiconductor laser component can be achieved, as the cover layer, which can serve as a heat brake, is removed.

According to at least one embodiment of the method for producing a semiconductor laser component, after the removal of the at least one cover layer, an intermediate layer is at least partially arranged on a region of the p-doped semiconductor layer. In particular, the region can thereby be complementary to the partial region that was activated in a previous method step. The region can thus be the further partial region. In other words, after removal of the at least one cover layer, an intermediate layer is at least partially applied to the unactivated region of the p-doped semiconductor layer. The intermediate layer can alternatively or additionally also at least partially cover an activated region of the p-doped semiconductor layer.

Furthermore, a further method for producing a semiconductor laser component is provided. The semiconductor laser component is preferably producible by a method described herein. In other words, all features disclosed for the semiconductor laser component are also disclosed for the further method for producing a semiconductor laser component and vice versa.

According to at least one embodiment, the method for producing a semiconductor laser component comprises epitaxially growing the n-doped semiconductor layer, the active layer and the p-doped semiconductor layer on top of each other, and activating the p-doped semiconductor layer, wherein the active layer is arranged between the n-doped semiconductor layer and the p-doped semiconductor layer. The p-doped semiconductor layer can, in particular, be completely activated.

According to at least one embodiment, the method comprises a method step in which a subregion of the p-doped semiconductor layer is deactivated to an unactivated region. The subregion can be, for example, a contiguous region or, for example, a region formed from at least two spaced-apart regions. When deactivating the subregion, hydrogen, for example, is introduced into the subregion. This can be done, for example, by applying a hydrogen-impermeable layer to the subregion of the p-doped semiconductor layer in a hydrogen-rich plasma.

According to at least one embodiment of the manufacturing process, the method comprises epitaxially growing an n-doped semiconductor layer, an active layer and a p-doped semiconductor layer on top of each other, wherein the active layer is arranged between the n-doped semiconductor layer and the p-doped semiconductor layer. The p-doped semiconductor layer is then activated. Subsequently, a subregion of the p-doped semiconductor layer is deactivated to an unactivated region of the p-doped semiconductor layer.

An advantage of this embodiment is that a semiconductor laser component with an activated and an unactivated region of the p-doped semiconductor layer can be produced.

According to at least one embodiment, deactivating a subregion of the p-doped semiconductor layer comprises the application of at least one cover layer. The cover layer contains, for example, a hydrogen-impermeable material or is formed from it. For example, the cover layer can be based on SiN and/or n-GaN. Among other things, the at least one cover layer can be applied to a partial region of the activated p-doped semiconductor layer in a hydrogen-rich plasma. The partial region adjacent to the cover layer applied in this way is deactivated, for example, in the method step in which the cover layer is applied.

According to at least one embodiment of the method for producing a semiconductor laser component, the at least one cover layer is removed after the deactivation step. For example, the cover layer can be removed by wet chemical means.

An advantage of this embodiment is that better heat dissipation of the semiconductor laser component can be achieved, as the cover layer can act as a heat brake.

According to at least one embodiment of the method for producing a semiconductor laser component, after removing the at least one cover layer, an intermediate layer is at least partially arranged on a region of the p-doped semiconductor layer. In particular, this region can be the subregion that was deactivated in a previous method step. An energization of the outcoupling facet can be reduced due to the electrically non-conductive or at least poorly conductive intermediate layer.

According to at least one embodiment of the method for producing a semiconductor laser component, a region of the p-doped semiconductor layer is damaged. This can mean that the lattice structure of the p-doped semiconductor layer is damaged in a region of the p-doped semiconductor layer facing the top side of the semiconductor body. The damage can be achieved by means of plasma etching or sputtering, for example. In sputtering, for example, a cover layer and/or intermediate layer is sputtered onto a partial region, for example onto the unactivated region of the p-doped semiconductor layer. Thus, damage to a layer of the p-doped semiconductor layer can be carried out simultaneously in one region, and a cover layer and/or intermediate layer can be applied to the unactivated region of the p-doped semiconductor layer.

An idea of this embodiment of the method is that the energization of the facets, in particular of the outcoupling facet, is further reduced due to the damage. The damage can, for example, take place in the same method step as the application of the intermediate layer to the unactivated region of the p-doped semiconductor layer. With this embodiment of the method, the semiconductor laser component can be produced in an uncomplicated manner.

According to at least one embodiment of the method for producing a semiconductor laser component, a region of the p-doped layer is damaged before the activation step. This region can in particular be a region of the later unactivated region.

According to at least one embodiment, the method for producing a semiconductor laser component is performed for a plurality of semiconductor laser components and the plurality of semiconductor laser components is subsequently separated into individual semiconductor laser components.

According to at least one embodiment of the manufacturing process, a highly reflective mirror is applied to the back facet. The highly reflective mirror contains, for example, at least one dielectric. In particular, the mirror can be formed with a layer stack comprising at least one dielectric.

In the following, the semiconductor laser component described herein and the method for producing a semiconductor laser component described herein will be explained in more detail in connection with exemplary embodiments and the associated figures.

### BRIEF DESCRIPTION OF THE DRAWINGS

FIGS. 1, 2, 3, 4, 5 and 6 show schematic cross-sections through a semiconductor laser component according to various exemplary embodiments.

FIG. 7 shows a schematic cross-section through the semiconductor laser component parallel to the outcoupling facet of the semiconductor laser component according to an exemplary embodiment.

FIG. 8 shows a step in a method for producing a plurality of semiconductor laser components according to an exemplary embodiment.

### DETAILED DESCRIPTION

Elements that are identical, similar or have the same effect are marked with the same reference signs in the figures. The figures and the proportions of the elements shown in the figures are not to be regarded as being to scale. Rather, individual elements may be shown exaggeratedly large for better visualization and/or better comprehensibility.

FIG. 1 shows a sectional view of a semiconductor laser component 100 with a semiconductor body 50.

The semiconductor body 50 comprises an n-doped semiconductor layer 1, an active layer 2, an undoped layer 3 as well as a p-doped semiconductor layer 4. The active layer 2 is thereby arranged between the n-doped semiconductor layer 1 and the p-doped semiconductor layer 4. The undoped layer 3 is arranged between the active layer 2 and the p-doped semiconductor layer 4. Alternatively or additionally, a further p-doped semiconductor layer, which comprises a lower dopant concentration than the p-doped semiconductor layer 4 can be arranged between the active layer 2 and the p-doped semiconductor layer 4. The semiconductor laser component 100 comprises the semiconductor body 50, a contact layer 14, an electrical contact 12 of the p-doped semiconductor layer 4 as well as a further electrical contact 13 of the n-doped semiconductor layer 1. The p-doped semiconductor layer 4 comprises at least one unactivated region 6 and at least one activated region 5. The contact layer 14 covers the activated region 5 and the unactivated region 6. The electrical contact 12 is arranged on the contact layer 14. The further electrical contact 13 is arranged on the side of the n-doped semiconductor layer 1 facing away from the active layer 2. The at least one unactivated region 6 comprises a higher hydrogen content and a lower electrical conductivity than the activated region 5. The at least one unactivated region 6 comprises, for example, an extension of at least 500 nm and at most 150 μm in a lateral direction x, which runs parallel to the main extension plane of the semiconductor laser component 100. The lateral direction x extends, for example, parallel to a resonator axis of the semiconductor laser component 100.

Further, the semiconductor laser component 100 comprises an outcoupling facet 15. The outcoupling facet 15 is arranged on a side surface of the semiconductor laser component 100. The unactivated region 6 of the p-doped semiconductor layer 4 is directly adjacent to the outcoupling facet 15. The outcoupling facet 15 can be a radiation exit surface, or the outcoupling facet 15 can comprise the radiation exit surface. The unactivated region 6 of the p-doped semiconductor layer 4 is adjacent to a side of the semiconductor laser component 100 on which the radiation exit surface is arranged. The semiconductor laser component 100 comprises a back facet 16. The back facet 16 is arranged at a side surface of the semiconductor laser component 100, which is opposite the outcoupling facet 15. Optionally, not shown, a further unactivated region 18 of the p-doped semiconductor layer 4 can be arranged directly at the back facet 16. The resonator axis extends, for example, from the outcoupling facet 15 to the back facet 16.

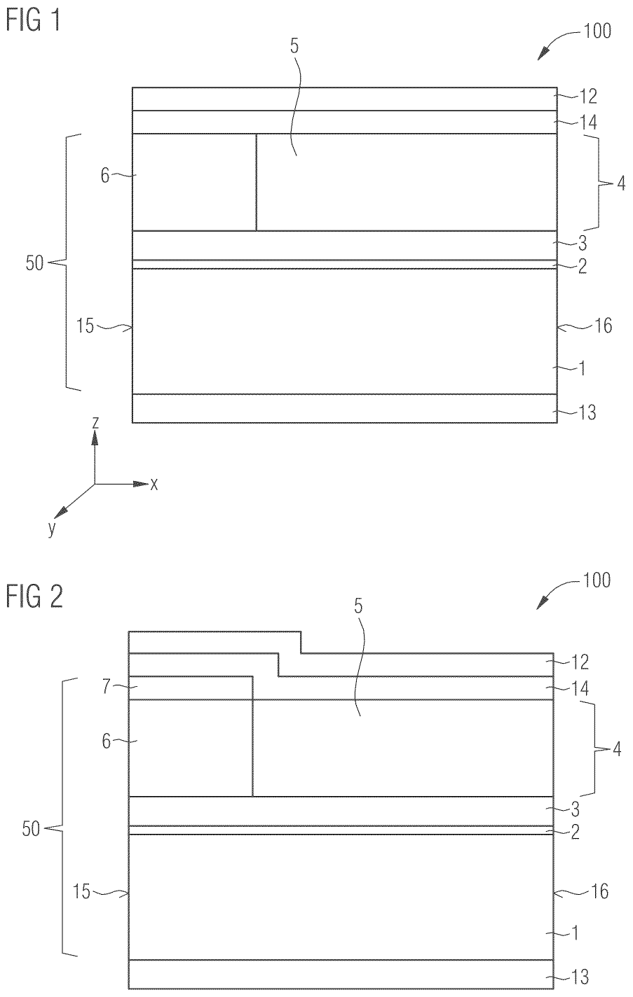

FIG. 2 shows a sectional view of a semiconductor laser component 100 according to a further exemplary embodiment. The semiconductor laser component 100 of FIG. 2 differs from the semiconductor laser component 100 shown in FIG. 1 in that a cover layer 7 is arranged on the unactivated region 6 of the p-doped semiconductor layer 4. In this exemplary embodiment, the semiconductor body 50 additionally comprises the cover layer 7. The cover layer 7 comprises, for example, a hydrogen-impermeable material, for example SiN and/or n-GaN.

On the basis of FIG. 2 an example of a manufacturing process for the semiconductor laser component 100 is explained.

First, an n-doped semiconductor layer 1, an active layer 2 and a p-doped semiconductor layer 4 are epitaxially grown on top of each other, wherein the active layer 2 is arranged between the n-doped semiconductor layer 1 and the p-doped semiconductor layer 4.

Subsequently, the p-doped semiconductor layer 4 is activated, for example by means of RTA. Then, a subregion of the p-doped semiconductor layer 4 is deactivated to an unactivated region 6. The deactivation comprises, for example, the application of a cover layer 7 to the subregion of the p-doped semiconductor layer 4.

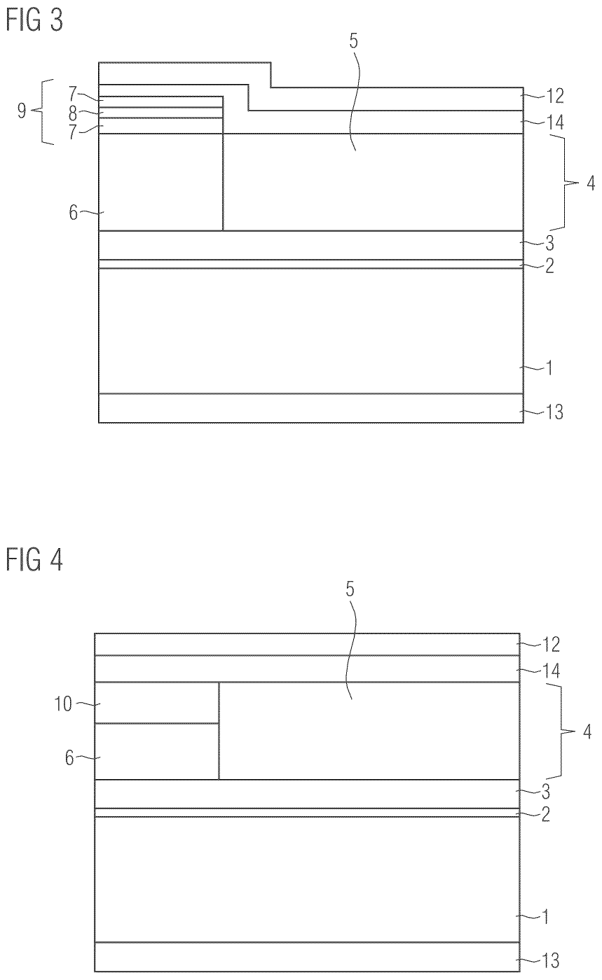

FIG. 3 shows a sectional view of a semiconductor laser component 100 according to a further exemplary embodiment. The semiconductor laser component 100 of FIG. 3 differs from the semiconductor laser component 100 shown in FIG. 1 in that a layer stack 9 is arranged on the unactivated region 6 of the p-doped semiconductor layer 4. The layer stack 9 comprises two cover layers 7 and a further cover layer 8.

FIG. 4 shows a sectional view of a semiconductor laser component 100 according to a further exemplary embodiment. The semiconductor laser component 100 of FIG. 4 differs from the semiconductor laser component 100 shown in FIG. 1 in that a side of the p-doped semiconductor layer 4 facing away from the active layer 2 comprises a region with a damaged lattice structure 10 at least partially in the unactivated region 6 of the p-doped semiconductor layer 4.

FIG. 5 shows a sectional view of a semiconductor laser component 100 according to a further exemplary embodiment. The semiconductor laser component 100 of FIG. 5 differs from the semiconductor laser component 100 shown in FIG. 4 in that an intermediate layer 11 is arranged on the region with damaged lattice structure 10. The intermediate layer 11 contains, for example, a dielectric.

On the basis of FIG. 5 an example of a further manufacturing process of the semiconductor laser component 100 is explained.

First, an n-doped semiconductor layer 1, an active layer 2 and a p-doped semiconductor layer 4 are epitaxially grown on top of each other, wherein the active layer 2 is arranged between the n-doped semiconductor layer 1 and the p-doped semiconductor layer 4. The p-doped semiconductor layer 4 comprises a partial region. Subsequently, a cover layer 7, not shown here, is applied to at least one further partial region of the p-doped semiconductor layer 4, which is different from the partial region that is activated in a subsequent method step. Subsequently, only a partial region of the p-doped semiconductor layer 4 is activated. The activation takes place using RTA, for example. The cover layer 7 is removed after the activation step. The further partial region of the p-doped semiconductor layer 4 is not activated and is therefore an unactivated region 6. A region of the unactivated region 6 of the p-doped semiconductor layer 4 is damaged. This region is subsequently the damaged region 10 of the p-doped semiconductor layer 4. After the removal of the cover layer 7, an intermediate layer 11 is arranged at least partially on a region of the p-doped semiconductor layer 4. In the embodiment shown here, the region is the unactivated region 6 with the damaged region 10 of the p-doped semiconductor layer 4.

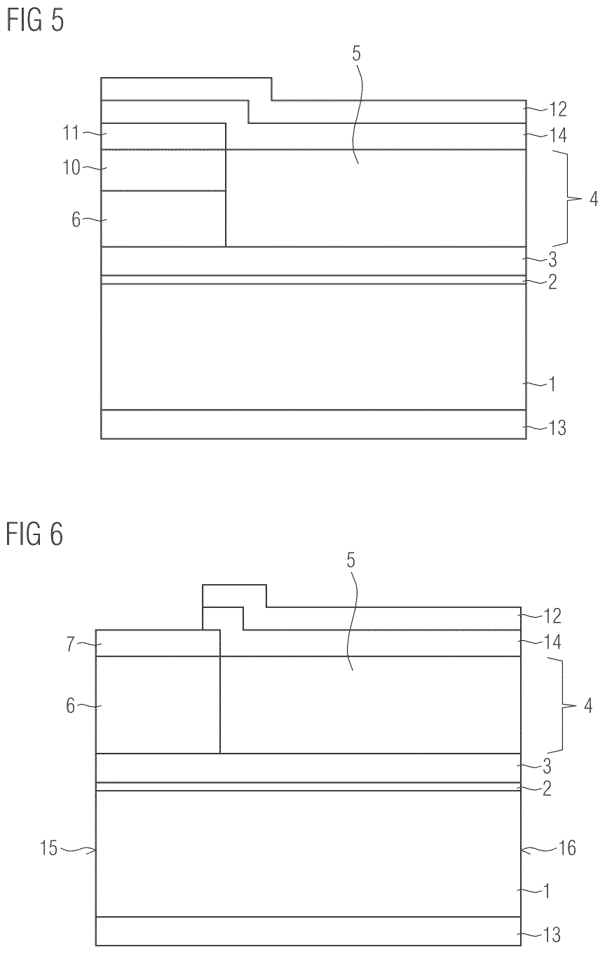

FIG. 6 shows a sectional view of a semiconductor laser component 100 according to a further exemplary embodiment. The semiconductor laser component 100 of FIG. 6 differs from the semiconductor laser component 100 shown in FIG. 2 in that the contact layer 14 and the electrical contact 12 of the p-doped semiconductor layer 4 do not completely cover the cover layer 7 arranged on the unactivated region 6 of the p-doped semiconductor layer 4. In other words, the contact layer 14 and the electrical contact 12 are retracted from the outcoupling facet 15.

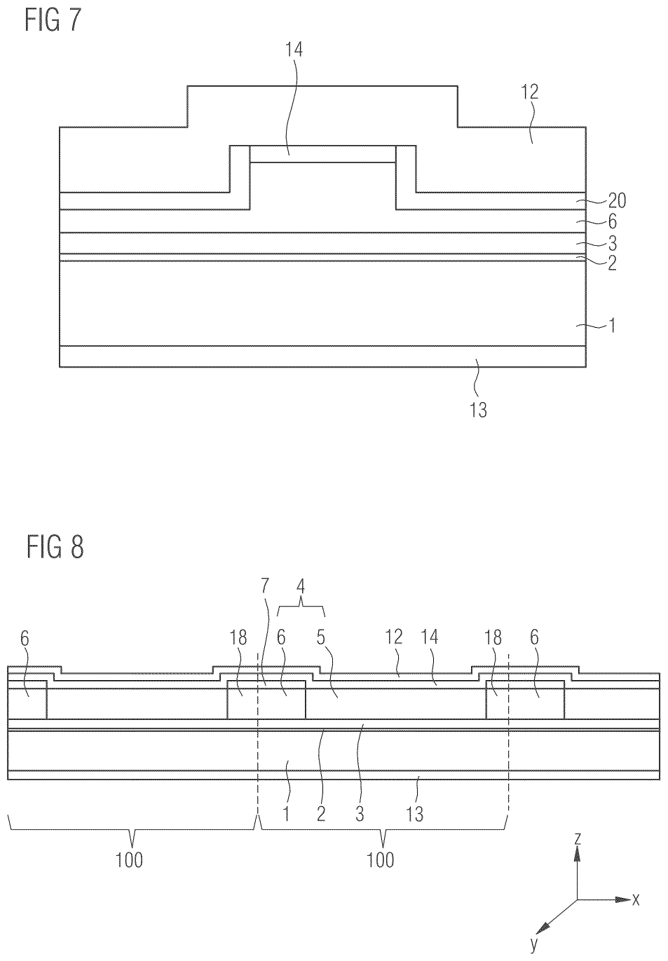

FIG. 7 shows a schematic cross-section through a semiconductor laser component 100 according to a further exemplary embodiment parallel to an outcoupling facet 15 of the semiconductor laser component 100. The semiconductor laser component 100 comprises an n-doped semiconductor layer 1, an active layer 2, an undoped layer 3 and a p-doped semiconductor layer 4. The p-doped semiconductor layer 4 comprises the unactivated region 6 adjacent to the outcoupling facet 15 and shown here. The unactivated region 6 is arranged at least along the radiation exit surface. In the region of the radiation exit surface, a contact layer 14 is applied to the side of the p-doped semiconductor layer 4 facing away from the active layer 2. The side surfaces of the radiation exit surface and the parts of the p-doped semiconductor layer 4 arranged outside the radiation exit surface are covered with a passivation layer 20. The passivation layer 20 can comprise, for example, a dielectric. The electrical contact 12 is arranged on the contact layer 14 and on the passivation layer 20. The further electrical contact 13 is arranged on the side of the n-doped semiconductor layer 1 facing away from the active layer 2.

FIG. 8 shows a step in a method for producing a plurality of semiconductor laser components 100. Thereby, the semiconductor laser components 100 are produced in an array and then cut along the dashed line. Preferably, a fracture edge extends through the unactivated region 6 of the p-doped semiconductor layer 4. After the separation step, the semiconductor laser component 100 comprises a p-doped semiconductor layer 4 with an activated region 5, an unactivated region 6 and a further unactivated region 18. The unactivated regions 6, 18 are directly adjacent to the fracture edge. The unactivated region 6 is arranged directly at the outcoupling facet 15, for example. The further unactivated region 18 is arranged directly at the back facet 16, for example.

The invention is not limited to the exemplary embodiments by the description thereof. Rather, the invention comprises any new feature as well as any combination of features, which includes in particular any combination of features in the patent claims, even if this feature or this combination itself is not explicitly stated in the patent claims or exemplary embodiments.

1. A semiconductor laser component comprising:
an n-doped semiconductor layer,
an active layer, and
a p-doped semiconductor layer, wherein
the active layer is arranged between the n-doped semiconductor layer and the p-doped semiconductor layer,
the active layer is designed to generate radiation,
the p-doped semiconductor layer comprises at least one activated region and at least one unactivated region,
the at least one unactivated region comprises a higher hydrogen content and/or a lower electrical conductivity than the activated region,
the activated region is arranged adjacent to the unactivated region in a main extension direction that runs parallel to a resonator axis of the semiconductor laser component, and
at least one cover layer is arranged on the at least one unactivated region of the p-doped semiconductor layer.

2. The semiconductor laser component according to claim 1, wherein the semiconductor laser component comprises at least one electrical contact and the unactivated region is arranged at least partially between the at least one electrical contact and the active layer.

3. (canceled)

4. The semiconductor laser component according to claim 1, in which a layer stack is arranged on the at least one unactivated region of the p-doped semiconductor layer, and the layer stack comprises at least one cover layer and at least one further cover layer.

5. The semiconductor laser component according to claim 1, in which at least one intermediate layer is arranged on the at least one unactivated region of the p-doped semiconductor layer, and the intermediate layer comprises a dielectric.

6. The semiconductor laser component according to claim 1, in which the at least one cover layer comprises silicon nitride and/or n-doped gallium nitride.

7. The semiconductor laser component according to claim 1, in which a side of the p-doped semiconductor layer facing away from the active layer comprises a damage at least partially in the at least one unactivated region of the p-doped semiconductor layer.

8. The semiconductor laser component according to claim 1, in which the at least one unactivated region comprises an extension of at least 500 nm and at most 150 μm in a lateral direction which runs parallel to the main extension plane of the semiconductor laser component.

9. The semiconductor laser component according to claim 1, in which the activated region of the p-doped semiconductor layer and the at least one unactivated region of the p-doped semiconductor layer are arranged next to each other in a lateral direction which runs parallel to the main extension plane of the semiconductor laser component.

10. The semiconductor laser component according to claim 2, in which the at least one electrical contact is electrically conductively connected to the activated region.

11. The semiconductor laser component according to claim 1, in which at least in places a contact layer is arranged on the side of the p-doped semiconductor layer facing away from the active layer.

12. The semiconductor laser component according to claim 1, in which the at least one unactivated region of the p-doped semiconductor layer is adjacent to a side of the semiconductor laser component at which the radiation exit surface is arranged.

13. A method for producing a semiconductor laser component, the method comprising:
epitaxially growing an n-doped semiconductor layer, an active layer and a p-doped semiconductor layer on top of each other, and
activating only a partial region of the p-doped semiconductor layer, wherein
arranging the active layer between the n-doped semiconductor layer and the p-doped semiconductor layer, and
applying, prior to activating the partial region of the p-doped semiconductor layer, at least one cover layer to at least one further partial region of the p-doped semiconductor layer which is different from the partial region,
wherein the at least one cover layer is impermeable to hydrogen.

14. (canceled)

15. The method for producing a semiconductor laser component according to claim 13, wherein the at least one cover layer is removed after the activation step.

16. The method for producing a semiconductor laser component according to claim 15, wherein, after the removal of the at least one cover layer, an intermediate layer is arranged at least partially on a region of the p-doped semiconductor layer.

17. A method for producing a semiconductor laser component, the method comprising:
epitaxially growing an n-doped semiconductor layer, an active layer and a p-doped semiconductor layer on top of each other,
activating the p-doped semiconductor layer, and
deactivating a subregion of the p-doped semiconductor layer to an unactivated region, wherein
the active layer is arranged between the n-doped semiconductor layer and the p-doped semiconductor layer, wherein the deactivation of the subregion comprising the application of at least one cover layer in hydrogen-rich plasma.

18. The method for producing a semiconductor laser component according to claim 17, wherein a region of the unactivated region of the p-doped semiconductor layer is damaged.

19. The method for producing a semiconductor laser component according to claim 13, wherein a region of the unactivated region of the p-doped semiconductor layer is damaged.
